(19) United States
(12) Patent Application Publication
(10) Pub. No.: US 2017/0121531 A1
(43) Pub. Date: May 4, 2017

(54) LOW TEMPERATURE-CURABLE ANTIREFLECTIVE COATINGS HAVING TUNABLE PROPERTIES INCLUDING OPTICAL, HYDROPHOBICITY AND ABRASION RESISTANCE

(71) Applicants: SEUNG-YEOL HAN, CORVALLIS, OR (US); Paul C. Ahrens, Corvallis, OR (US); John Arthur DeVos, Corvallis, OR (US)

(72) Inventors: SEUNG-YEOL HAN, CORVALLIS, OR (US); Paul C. Ahrens, Corvallis, OR (US); John Arthur DeVos, Corvallis, OR (US)

(21) Appl. No.: 15/129,403

(22) PCT Filed: Mar. 25, 2015
(86) PCT No.: PCT/US15/22593

§ 371 Date: Sep. 26, 2016

Related U.S. Application Data
(60) Provisional application No. 61/969,842, filed on Mar. 25, 2014.

(51) Int. Cl. C09D 5/00; H01L 31/0216; G02B 1/111; C03C 17/02; C09D 183/02

(52) U.S. Cl. CPC C09D 5/006; C03C 17/02; C09D 183/02; G02B 1/111; H01L 31/02168; C03C 2217/213; C03C 2217/73; C03C 2218/11; C03C 2217/78

(57) ABSTRACT

Disclosed herein is an inventive low-temperature curable antireflective (AR) coating produced by a single layer sol gel deposition process comprising a low-temperature curing step, whereby temperatures well below 100° C. for under 8 hours result in highly robust AR coatings having excellent transmittance and abrasion resistance. Optical, mechanical and chemical properties may be tuned by adjustment of the formulation of the wet coating solution. In this way, the inventive AR coating is able to provide enhanced mechanical and moisture resistance, as well as superior optical performance that can be optimized to suit a particular environment. The innovation advantageously enables applying AR coatings to substrates installed in the field, allowing passive heating of the substrate by sun exposure to provide the heat for curing the inventive coatings outdoors.

### CROSS REFERENCE TO PRIORITY APPLICATIONS

This non-provisional utility application is filed under the provisions of 35 U.S.C. 371(c), and 37 CFR 1.495, as the national phase of PCT Application No. PCT/US15/22593 designating the United States, filed on Mar. 25, 2015, of which the 30 month international pendency ends on Sep. 25, 2016. The aforementioned PCT application claims the benefit of U.S. Provisional Application No. 61/969,983, filed on Mar. 25, 2014, under the provisions of 35 U.S.C. 119(e).

### FIELD OF THE INNOVATION

This innovation relates to low temperature-curing antireflective coatings with tunable properties.

### BACKGROUND

Energy transmission enhancement coatings are thin-film dielectric optical coatings that augment the transmission of infrared, visible and ultraviolet light to surfaces of transparent and non-transparent substrates. Enhanced transmission of light energy to photovoltaic cells provides an advantage by increasing the number of photons available for electricity production. Energy transmission improvement coatings, again in the form of antireflective coatings, may also provide an advantage for glass windows by reducing the light reflected off of the surface, reducing the glare normally emanating from glass surfaces. Increased energy transmission, in the form of increasing the number of photons transmitted through the glass from outside a building to the inside of the building, may also reduce the need for interior electric lighting.

Such coatings serve to reduce reflected light, and increase transmission by acting as a refractive index-matching layer, forming a gradient of refractive index from that of air to that of the substrate, within a layer approximately ¼ wavelength in thickness, where the wavelength band of light may be chosen by adjusting the thickness and the material of the coating. Thin dielectric films formed on a reflective surface can provide a refractive index match between the substrate and the surrounding medium, typically air, if the film has a refractive index intermediate between the substrate and air. In addition, a thin film necessarily presents more than one reflective interface from which incident light can reflect to create destructive interference conditions suppressing the light reflected from each interface.

Anti-reflective (AR) thin films or coatings are examples of such energy transmission enhancement coatings To this day, the optical principles originally laid out by Rayleigh and others to explain the AR effect govern the design objectives of modern engineered AR thin film coatings. Modern thin-film deposition methods and nanotechnology are employed to produce advanced coatings. Present commercial coatings comprise both single and multilayer coatings, which may be deposited by so-called dry deposition techniques, such as RF sputtering or vapor deposition techniques (i.e., magnesium fluoride), or by wet methods. Sol gel methods are particularly used as wet deposition techniques, and are able to be carried out in non-laboratory environments, do not require expensive high-vacuum systems, and use inexpensive starting materials.

Recent efforts have produced advanced AR coatings, and optical coatings in general, where attention is paid to optimizing mechanical properties as well as optical properties. Examples of improved AR coatings are abundant in many recently published patent applications and issued patents. These more advanced coatings rely on multilayer wet deposition comprising an adhesion layer, followed by one or more engineered optical layers that are by themselves mechanically weak. By focusing on optimizing optical properties, many commercial AR coatings suffer from inferior mechanical properties, such as low abrasion resistance, brittleness, short lifespan and low thermal/chemical stability.

Many optical layers for use as AR coatings may comprise nanoparticles, particularly hollow nanoparticles to effectively provide a nanoporous medium of low refractive index for improved reflection suppression. Furthermore, the optical layers may be capped by a protective layer to ensure mechanical protection of the entire coating from environmental stresses experienced by the substrate. Some of these protective layers feature organo-silicate cross-linking components combined with silicate-based sol gels to form the protective layers. In all cases, the manufacture of multiple layer coatings is inherently more expensive and complicated in comparison to application of a single layer. No examples are currently available describing a single layer optical coating having both optimized optical and mechanical characteristics. Moreover, no example of an optical coating method or process exists to produce a single layer optical coating with tuned optical, mechanical and chemical properties on demand, whereby the important properties can be easily tuned to meet the environmental demands of the substrate.

In many coating processes, curing temperatures for producing optical coatings such as AR coatings are typically carried out well above 100° C., typically over 500° C., to have a reasonable curing times. This may limit or preclude the production of scratch-resistant AR coatings on delicate substrates, or heat-sensitive substrates made from polymers, layered semiconductor photovoltaic structures, and low melting metals, such as aluminum. Furthermore, the high curing temperatures preclude the possibility of applying optical coatings outside of a manufacturing environment, where specialty ovens or heat treating assembly lines are necessary to applying and baking optical coatings on large substrates such as photovoltaic panels. Efforts have been made to make available less expensive liquid sol-gel coating precursor solutions for panel manufacture, and in recent years many new panels are produced with AR coatings.

In many cases, older photovoltaic and solar thermal panels that do not have an AR coating have been part of a working installation, such as a multi-panel solar array, for a number of years. As such panels have many years of service lifetime left, it may be desirable to retrofit these panels with the newer sol-gel optical coatings, such as AR coatings, taking advantage of their lower costs, to increase the solar energy conversion efficiencies by 3-4 percentage points. Over time for large arrays, these small increases in conversion efficiency translate to significant increases in profit margins for commercial operations.

However, the curing conditions required by present day commercially available sol-gel coating precursor solutions involve high temperature baking regimes of approximately 200° C. to over 500° C. in order to produce sufficiently robust optical coatings. These high-temperature conditions thus require dismantling of the installation in order to deliver the panels to a special facility or return them to the factory of origin to reprocess the panels with the optical coatings. The endeavor is highly disruptive and costly both in downtime and processing costs. Ideally, the panels could be coated on site, without the need to dismantle them and ship them off-site. If a low-temperature curing formulation could be developed, whereby the heat of the sunlight captured by the substrate can be harnessed to cure a precursor sol-gel solution to high quality optical coatings in a relatively short time, on panels in an existing outdoor installation.

As an example, sun-curing at ambient temperatures ranging from 10° C. to 40° C. can heat the surface of the substrate to temperatures ranging from about 30° C. to over 100° C. For such an application, a low-temperature curable coating composition that results in a highly robust optical coating is required, where in addition to the low-temperature curability, the resulting coating film has very high abrasion durability, humidity resistance, and high optical transmittance over a large spectral range

### SUMMARY OF THE TECHNOLOGY

The instant innovation is a single-layer energy transmission enhancement coating having tunable optical (transmittance), hydrophobicity (moisture resistance) and hardness (abrasion resistance) characteristics. The energy transmission enhancement coatings are a class of optical coatings including, but not limited to, quarter wavelength anti-reflective (AR) coatings, where the thicknesses may be on the order of several hundred nanometers. In addition, the instant innovation provides for low-temperature coating and curing process for applying a novel liquid sol-gel precursor coating solution formulation that results in the instant single-layer coating with the enhanced properties.

By single-layer, it is meant that the final coating is substantially compositionally uniform across its thickness. When describing the coating process, it may be indicated that a single pass or double pass is used to deposit the coating precursor solution. According to the instant innovation, it is to be understood that this terminology may indicate that compositionally or structurally heterogeneous layers are deposited, as is commonly done in the art. According to the innovation, a multiple pass deposition process, such as a double pass, involves coating two or more layers of the same or different precursor solution of the same composition, resulting in a energy transmission enhancement coating that may or may not be substantially compositionally and structurally uniform across its thickness.

Thus the term “single layer” is used throughout this disclosure to describe the resulting innovative energy transmission enhancement coating as being substantially compositionally and structurally uniform across its thickness. In other instances, the coating prepared by a multiple pass process may be non-uniform across its thickness. It is an object of the instant innovation that the energy transmission enhancement coating is curable at low temperatures. For example, the inventive coating solution may be cured at 50° C. for 8 hours and provide excellent abrasion resistance. This is contrasted to more conventional coating compositions that require substantially more time to cure at such low temperatures, resulting in films that may have poor abrasion resistance. As a result of the excellent performance of the low temperature curing process, the innovation provides for sun-curable AR coatings, allowing for, as an example, retrofitting a solar panel installation in the field with durable AR coatings whereby the coating is cured only by passive solar thermal energy.

The cured coating layer may comprise hollow-spherical and/or solid silica nanoparticles or nanospheres that comprise a size distribution ranging from 2-200 nm. In all cases the cured coatings of the instant innovation comprise a cross-linked silica matrix incorporating into its structure at least one hard coat siloxane agent. The aforementioned components are mixed as sol-gel coating precursors in the liquid state, and then deposited onto a substrate in the liquid state by various deposition means with a subsequent curing treatment to produce a durable coating ranging between 50 nm and 250 nm in thickness, whereby the deposition process and composition of the precursor coating solution are tunable to enable desired spectral characteristics. Accordingly, the inventive optical energy transmission enhancement coating can be prepared with a range of predictable hydrophobicity and abrasion resistance, by variation of the concentration of at least one of the coating precursors in the coating solution formulation, as well as the curing treatment. In some embodiments, the concentration of the siloxane can be varied to produce predictable changes in the hydrophobicity and durability of the inventive coating.

The instant innovation thus provides the advantage of tailoring the moisture resistance (hydrophobicity) and hardness of the coatings by tailoring the coating composition to suit durability requirements dictated by the particular application to which the substrate is subjected. It is one aspect of the instant innovation to provide ranges of composition ratios of the prepared inventive AR coating that are correlated with surface and bulk properties (do we have these correlations?). The coating process may be carried out by a variety of methods, including but not limited to: spray-coating, dip coating, roller coating and brush coating.

Furthermore, the thickness of the film may be tailored by the judicious choice of the coating process and adjustment of coating parameters, including viscosity of the coating precursor solution. The inventive optical coating may be prepared as a single layer coating or in multiple layers. In some embodiments, the inventive optical coating may be prepared by applying a single pass of coating precursor solution, or by applying a double pass coating, where the first pass is the application of the coating precursor solution, curing or partially curing the first layer, and then applying a second layer of the same coating precursor solution, or a different solution, such as a hard coat, where the second coating solution may be compositionally distinct from the first layer.

For the purposes of this disclosure, the substrate may be a solar photovoltaic panel, a solar thermal panel, a sheet window glass, an eyeglass lens, or any other transparent or non-transparent object having at least one reflective surface where it is desired to suppress the reflectivity. In this way, the durability requirements of an energy transmission enhancement coating on, for instance, a photovoltaic or solar thermal panel may be satisfied by the selection of one set of coating precursor component ratios from a coating precursor component ratio continuum disclosed herein to yield coatings of the requisite durability. Conversely, an energy transmission enhancement coating such as an AR coating applied to substrates having less stringent durability requirements, said requirements being satisfied by the selection of another set of coating precursor component ratios from the same continuum of coating precursor component ratios disclosed herein.

It is one aspect of the instant innovation to provide an energy transmission enhancement sol-gel coating that may be applied and cured in the field, where the term “field” indicates application of the coating to substrates such as solar panels in an outdoor array installation, where the array can consist of a single panel or multiple panels. The term “substrate” most commonly indicates panels of the type referred to above, viz, photovoltaic panels and solar thermal panels, but may also include glass windows installed in structures. Therefore, instant innovation includes a field coating process, and the finished energy transmission enhancement coating product produced by the innovative process. However, the term field may not be limited to out-of-doors environments, and can include indoor installations, or those existing in an enclosed structure.

### BRIEF DESCRIPTION OF THE DRAWINGS

FIG. 1. TEM micrograph showing and example of thin-shell hollow nanoparticles that may be used in the inventive energy transmission enhancement coating.

FIG. 2. TEM micrograph showing an example of thick-shell hollow nanoparticles that may be used in the inventive energy transmission enhancement coating.

FIG. 3. SEM cross-sectional view of the energy transmission enhancement coating deposited on a thin-film semiconductor layer on a glass substrate.

FIG. 4. Zoom of view shown in FIG. 3, revealing structural details of the inventive energy transmission enhancement coating.

FIG. 5. Transmission spectral comparison between coated (inventive AR coating) and uncoated smooth glass substrate.

FIG. 6. Transmission spectral comparison between coated and uncoated textured glass substrate.

FIG. 7. Transmission spectral comparison between coated and uncoated smooth acrylate (PMMA) substrate. Upper graph shows comparison of the transmission spectra of the uncoated and coated substrate, and lower graph shows % ΔT.

FIG. 8. Results from abrasion scrub test. Comparison of transmission spectra of virgin single pass coating and same after abrasion scrub test. See text for test conditions.

FIG. 9. The change in transmittance (% ΔT) of the innovative coating after the abrasion scrub test. Same substrate as in FIG. 8

FIG. 10. Results from abrasion scrub test on a double-pass coating. Comparison of transmission spectra of virgin double-pass coating and same after abrasion scrub test.

FIG. 11. Results of HAST testing. A single-pass coating subjected to HAST conditions. See text for test conditions.

### DETAILED DESCRIPTION

The tunable coating property aspect of the instant innovation may be derived in part through variations in the deposition process. In some embodiments this may be accomplished by varying the thickness of the coating. The tunable coating property aspect of the instant innovation may be derived in part from variation of the final composition of the coating, which in turn is determined by the relative amounts of precursors in the wet coating precursor solution, or precursor ratio, can be selected from a continuum of precursor ratios disclosed herein to produce desired coating characteristics. In some embodiments, the concentration of the siloxane component is changed to yield desired properties. Siloxanes or hardcoats are available through a variety of manufacturers. An example of a hardcoat is poly dimethyl siloxane (PDMS) and derivatives.

### Formulation

In some embodiments, the dry content composition of the inventive AR coating may comprise the following composition ranges in terms of solids content (dry weight percentages):

Matrix/Silicate: 60-100%

Siloxane: 0-20%

Nanoparticles (hollow and/or solid): 0-20%

In other embodiments, the dry composition may comprise the following ranges:

Matrix/Silicate—76-90%

Siloxane—5-12%

Hollow NP—5-12%

### General Coating Precursor Solution

The matrix sol gel precursor is derived from base-catalyzed hydrolysis of an organic orthosilicate, for example tetramethyl orthosilicate (TMOS) or tetraethyl orthosilicate (TEOS). Sol gel creation from organic orthosilicates such as TMOS and TEOS is well known in the art, and the exact concentrations and final pH adjustments of the acid and base catalysts can vary. Many examples of particular conditions can be found in both the patent and scientific literature.

One embodiment of the coating precursor solution is formulated as a mixture of the following at room temperature:
Organic orthosiicate (TMOS) sol gel concentration can range up to 50% in alcohol-base-catalyzed
Hardcoat siloxane concentration can range up to 50% in alcohol
Hollow-spherical nanoparticle (HSNP) concentration can range up to 50% as an alcoholic suspension
wherein the alcohol may comprise any one of C1 to C10 alcohols and mixtures thereof. Any suitable solvent known to those skilled in the art may be used.

The volumetric ratios of the individual coating precursor solutions may be adjusted to yield precursors having the following concentrations based on ratios of one to the other or final percentages in solution:

HSNP 0-20%

Hardcoat 0-20%

### Example of Low Temperature Curing AR Coating Composition

A low temperature curing AR coating solution composition comprises the following components. Base-catalyzed orthosilicate tetramethyl orthosilicate (TMOS-b) system is prepared, by mixing TMOS, water, methanol or ethanol, and a base catalyst that may include any of the following basic compounds: ammonia, organic amines (RNH₂, R₂NH, R₃N, where R=C₁₋₃ alkanes), basic amino acids (arginine, lysine) and quartenary ammonium halides, where the quartenary ammonium ion has the formula RNMe₃, where R=C₆₋₁₂ alkanes.

A pre-mixture of 4:1 TMOS-b binding agent is prepared. TMOS-b tends to polymerize into long linear chains and does not extensively cross-link. A binding agent that undergoes hydrolysis during curing, forming linear or branched structures at low temperature, occurring readily under 100° C., is added as well. In the inventive energy transmission enhancement coating composition, the binding agent may be used as a minority reagent in combination with TMOS-b to provide for the cross-linking of the long linear silicate chains made by the polymerization of TMOS-b. The combination of the binding agent and TMOS-b in the composition disclosed advantageously cures to form hard scratch resistant coatings at substantially lower temperatures for less curing time than previously disclosed coatings of similar composition.

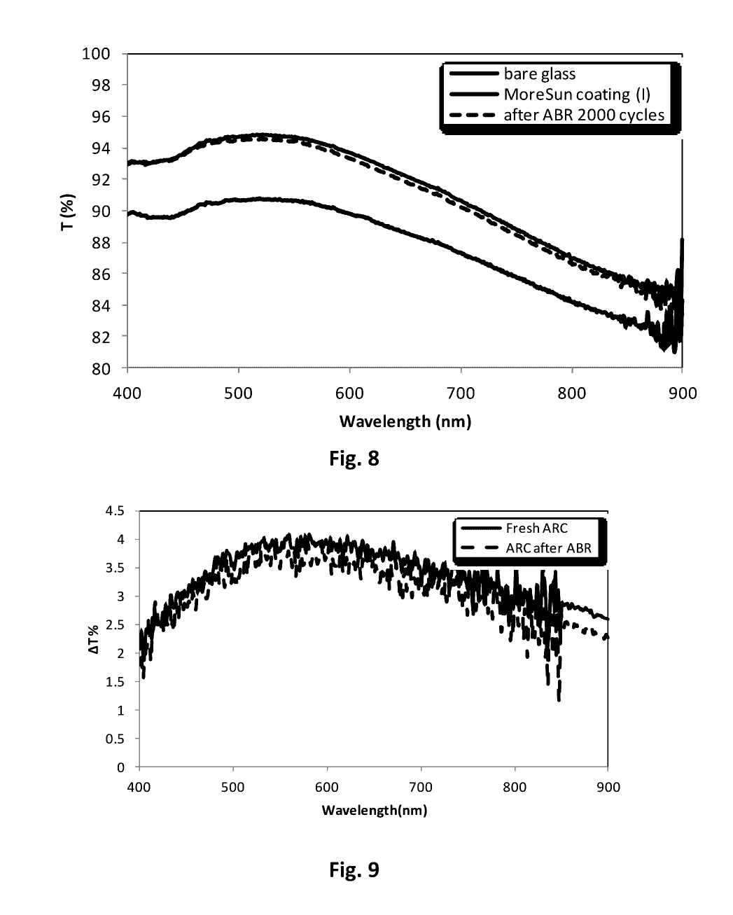

The novel AR coating composition further comprises organosilane additives for improvement of hydrophobicity, and any of the organosilanes having the structure (R₁)ₙSi(O R₂)₄₋ₙ (R₁, R₂: C₁₋₃ alkane, alkene, n=0-3) and RSiCl₃ (R: C₁₋₃ alkane, alkene) have been found to may be added in varying ratios to the binder: TMOS-b mixture. Optical properties of the coatings are controlled using both solid and hollow sphere silica nanoparticles, described below. In other embodiments, no nanoparticles are added to the mixture. Low temperature-curable coatings according to the innovation form high transmittance and excellent abrasion resistance (see FIGS. 8-10) when cured at, for example, 40° C. for 24 hours, 50° C. for 8 hours, 65° C. for 4 hours, 150° C. for 1 hour. This contrasts more typical curing regimes of curing temperatures ranging between 90° C.-700° C. for 10 minutes or less for the higher temperatures, up to five hours for the lower temperatures. Such a treatment may yield a film thickness ranging between 50-250 nm. Other thermal treatment regimes, as well as more exotic plasma and microwave methods are not excluded.

Formulations for the low temperature AR coating solution compositions may comprise the following ranges:

### Without Nanoparticles

### TMOS-b (Matrix/Silicate): 50-95%

### Binder: 5-50%

### With Nanoparticles

### TMOS-b (Matrix/Silicate): 60-90%

### Binder: 5-20%

Nanoparticles (hollow and/or solid): 5-20%

### Nanoparticle Addition

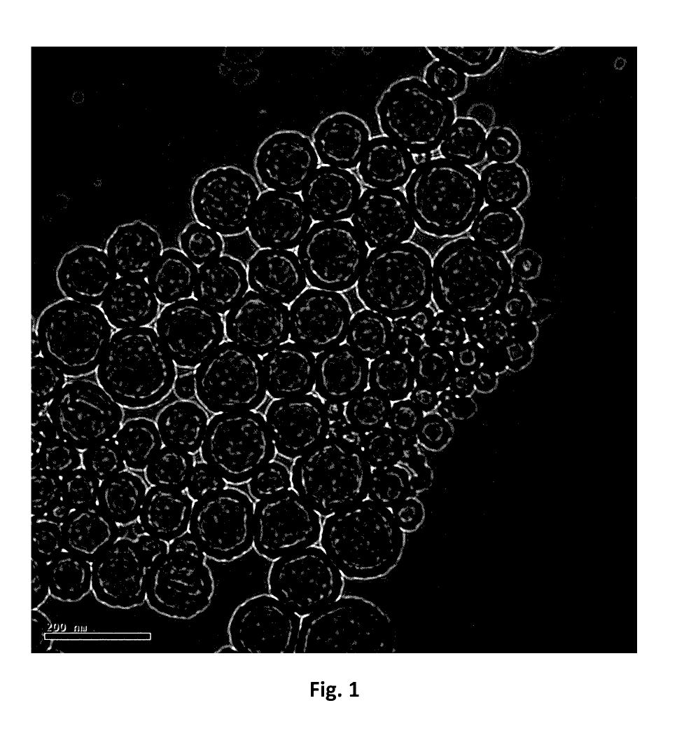

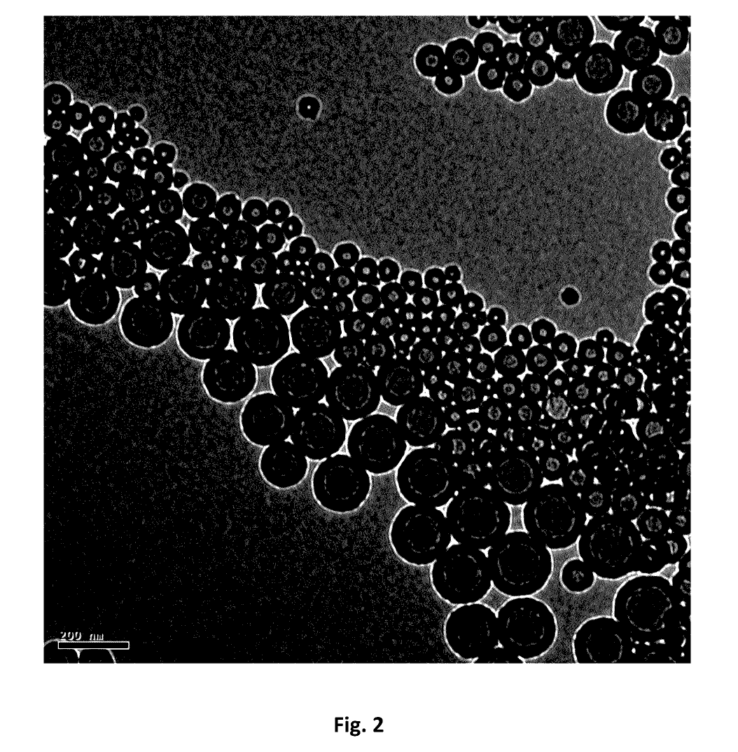

It may be desired to incorporate added hollow silica nanoparticles to the precursor coating solution. Syntheses of hollow spherical silica nanoparticles are well known in the art. Many examples of silica HSNP can be found in both the patent and scientific literature. FIGS. 1 and 2 are transmission electron micrographs showing typical examples of silica HSNPs prepared and used in the inventive energy transmission enhancement coating solution.

FIG. 1 shows thin-shell hollow nanoparticles, whereas FIG. 2 depicts thick-shell hollow nanoparticles. Procedures to synthesize hollow nanoparticles are abundant in the patent and scientific literature. In terms of size, the hollow nanoparticles can range between 5 to 200 nm. In terms of distribution, the hollow nanoparticles can be within a narrow size range, or within in a bimodal size range, a trimodal size range, multimodal or completely random size distribution. In addition to hollow nanoparticles, solid nanoparticles may be incorporated into the film. One such method is to procure solid nanoparticles from a commercial source and incorporate them into the solution mix prior to making the film.

Incorporation of pre-synthesized nanoparticles creates additional costs to manufacture the innovative coating precursor solution. The instant coating precursor solution does not incorporate the addition of pre-synthesized nanoparticles, and instead produces a coating where nanoparticles may form spontaneously.

### Example of Coating Panel Substrates on in the Field

The coating deposition comprises mixing the individual coating precursor components together to form the coating solution. The coating solution is then deposited on a substrate using a coating apparatus adapted to coat substrates such as photovoltaic panels and solar thermal panels already existing in a field installation. Such a coating apparatus is described in detail in co-pending U.S. Utility patent application Ser. No. 14/668,956, incorporated herein by reference in its entirety, but coating apparatuses for the purpose of this disclosure are not limited to any particular type, and in general comprise a coating distribution means.

The coating distribution means include, but are not limited to, spray coating nozzles, brushes and contact applicators of the like. This point is explained below. By virtue of the capability of the inventive coating precursor solution to cure at temperatures well under 100° C., the ability to retrofit or re-coat substrates in existing installations with an optical coating, such as an antireflective coating, is provided. This improvement eliminates the need to dismantle the substrate from the installation to send it to the factory of origin or to a special facility for coating, avoiding a costly and disruptive maintenance procedure.

The installations referred to in this disclosure comprise a single substrate, such as a single individual photovoltaic panel, or an array of multiple panels, as in a photovoltaic array. The term “array” is meant to be understood to consist of a single panel or multiple panels. Substrates may be extended to include solar thermal panels, regarded individually (single panel arrays) or in multi-panel arrays. In addition, glass window panes installed in residential and commercial buildings are included in the definition of substrate as well for the purposes of this disclosure.

A coating apparatus may be a standard one known in the art to make thin-film coatings, such as, by way of example, a roll coater, spin coater, dip coater and spray coater. The coating process may be carried out at ambient temperatures, but temperatures both above and below ambient are not excluded. Coating thickness may be controlled by certain coating parameters, such as the viscosity of the coating solution, speed of a moving substrate, and/or the curing process, as described below.

In some embodiments, the coating is applied to a substrate, such as a solar photovoltaic panel installed in an outdoor photovoltaic array, by use of the coating apparatus disclosed in co-pending U.S. Utility patent application Ser. No. 14/668,956, incorporated by reference herein in its entirety. The coating apparatus disclosed therein is adapted to deposit an optical thin-film coating layer of uniform thickness by use of innovative coating heads, or brushes, on substrates such as photovoltaic panels in both indoor and outdoor installations.

For the purposes of this disclosure, the substrate is disposed in an ambient, where an ambient can be defined either as an indoor or outdoor environment. “Outdoors”, or “out of doors” is defined as being outside, or disposed in the open environment, whereas “indoors” is defined as being inside, or disposed in the interior of an enclosed structure, such as a building. For purposes of this disclosure, “field” is used, such as “field-coated”, to mean the coating process takes place outside of a facility where the substrate would normally be manufactured, and rather the inventive coating process occurs in an individual or array installation of the substrate, typically out of doors.

An example coating procedure is the following:

A substrate is provided, where the substrate can be any one of the following: a photovoltaic panel, a solar thermal panel, a glass pane. In practical terms, the substrate may be referred to as a panel or pane, and may be part of an existing installation, either as a single panel or multi-panel array, for photovoltaic and solar thermal installations, or as glass windows installed in a structure. As discussed above, a coating apparatus is provided, comprising a coating distribution means.

Such a coating distribution means may be based on a brush methodology where the coating distribution means is an applicator head having one or more brushes in intimate contact with the substrate surface, applying a uniform layer of liquid coating precursor solution on the substrate, where the coating distribution means is capable of applying a liquid coating layer that may be less than or equal to 20 microns in thickness. Such a coating means is described in detail in co-pending U.S. Utility patent application Ser. No. 14/668,956, incorporated herein by reference in its entirety. Alternatively, the coating distribution means may be based on a spray methodology, where one or more spray nozzles are used to apply a uniform layer of optical-coating precursor solution to the substrate, where the nozzles are positioned at a distance above the substrate surface.

The coating apparatus may be positioned on the substrate surface, which for photovoltaic panels or solar thermal panels, may be inclined at an obtuse angle with respect to the vertical. As an example, the coating apparatus may be placed on the lower end of the panel. The coating apparatus may be hand-driven, in which case it may have an elongated handle attached to it. An operator may then move the coating apparatus along the substrate surface in an excursion from the initial position to the upper end of the substrate. For a brush applicator, the one or more applicator heads may be engaged on the surface during the excursion. Alternatively, the applicator heads may be engaged during the return excursion, or during both excursions. The coating apparatus may also be adapted to move in a grid pattern, being displaced laterally. The foregoing is also true for a coating apparatus having a spray distribution means.

A thin film layer of the inventive precursor solution is then applied to either the entire surface of the substrate, or a portion thereof, with a substantially uniform thickness. In some embodiments, the precursor layer is of such a thickness that a cured coating thickness of 50-250 nm will result. Moreover, the coating may be deposited in a single pass or by multiple passes, where the same or different coating precursor solution is deposited over a previous coating layer of the same composition.

In some embodiments, the innovative coating is prepared as a single-pass layer or a double-pass layer. In other embodiments, the coating apparatus is motorized, where a motor drive is engaged with the traction means of the coating apparatus, and provides a constant speed of translation of the apparatus. The constant speed is one form of operation, as the rate of deposition of the layer is a strong function of the speed of translation of the apparatus. By precise control of the speed of the coating apparatus during its coating excursions, the final thickness of the layer is well controlled and spatially uniform. This is best done by a motorized coating apparatus. In this manner, the thickness may readily be tuned to ¼ wavelengths of target portions of the solar spectrum or other ambient lighting.

The precursor layer may now undergo a curing step, wherein the substrate, as part of an outdoor installation, is passively cured out of doors in the sun at ambient temperatures. In some embodiments, the substrate surface temperatures range from 10° C. to over 100° C. Surface temperatures such as those figuring in the quoted range may be engendered by ambient sunlight, and related to air temperature, which is primarily dictated by weather conditions, season and geographic location. According to the innovation, the warmer the substrate surface temperature, the faster the curing process occurs.

Alternatively, the curing process may take place under conditions of low light levels, or in the dark entirely, as the curing chemistry is a thermal process. As an example, a coated substrate in an outdoor installation may be cured under cloud cover, or at night. Moreover, the substrate may be cured indoors, where the surface temperature is approximately the ambient temperature.

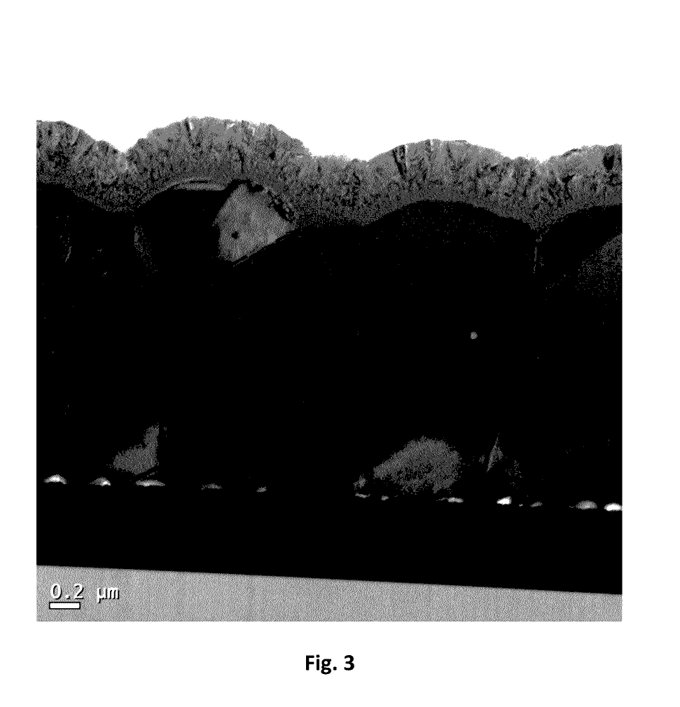

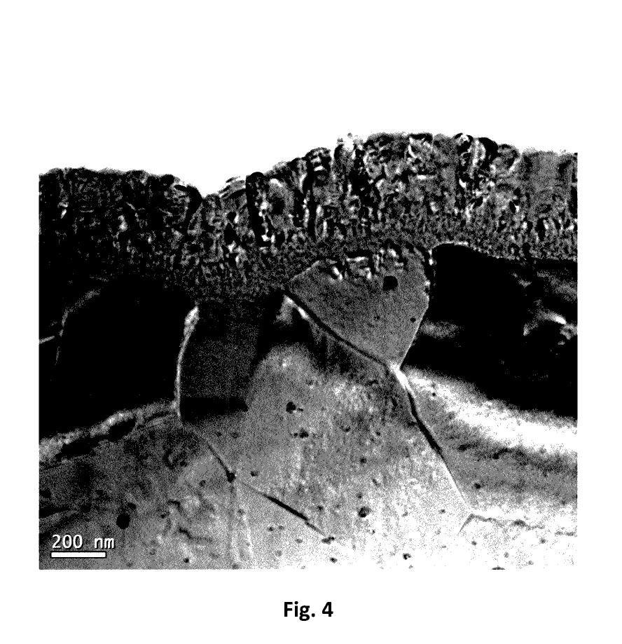

A cross sectional view of the innovative cured coating is shown in the SEM micrographs of FIGS. 3 and 4. FIG. 3 shows a cross-sectional view of the innovative coating on a thin-film photovoltaic device deposited on a glass substrate. FIG. 4 shows a zoom of the interfacial portion of the device, having the innovative coating applied at the surface of the device. The surface in the case of the photovoltaic film is uneven, and the innovative coating can be seen forming a smooth optical film above. The innovative coating shown in FIGS. 3 and 4 incorporate nanoparticles. The innovative coating is a single layer coating, as explained above, being substantially compositionally and structurally homogeneous across its thickness.

### Optical Performance

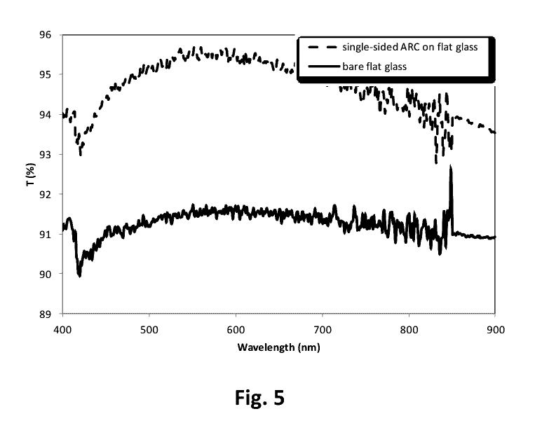

The effect of using the inventive AR coating on glass and plastic substrates is shown in FIGS. 5-7. In FIG. 5, the visible wavelength transmission spectra are shown for a smooth flat window glass substrate. The upper curve represents the glass substrate coated with the inventive energy transmission enhancement coating, in this case intended as an AR coating, on one side. The data show an improvement of transmission (ΔT) of up to 4% between 500 and 600 nm, and minimum 3% elsewhere, with an average gain in transmittance of 3.65%.

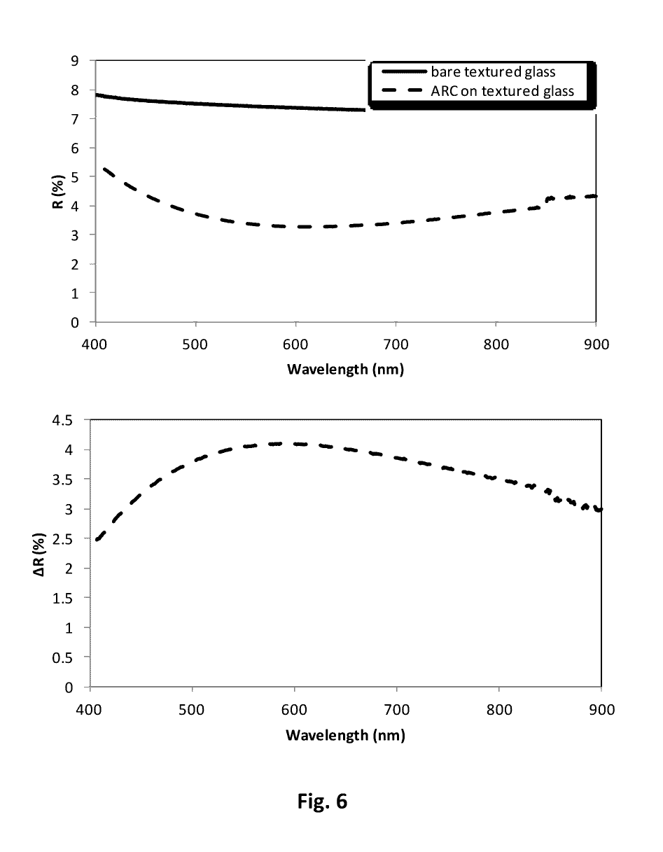

Direct reflectance measurements on textured glass are shown in FIG. 6. Here, the data show the decrease in reflected light (upper graph, dashed curve) across the visible spectrum due to the presence of the inventive energy transmission enhancement coating. The average decrease is 3.73%. In the lower graph of FIG. 6, the dashed curve represents the change in reflectance from the surface of the substrate coated with the innovative coating.

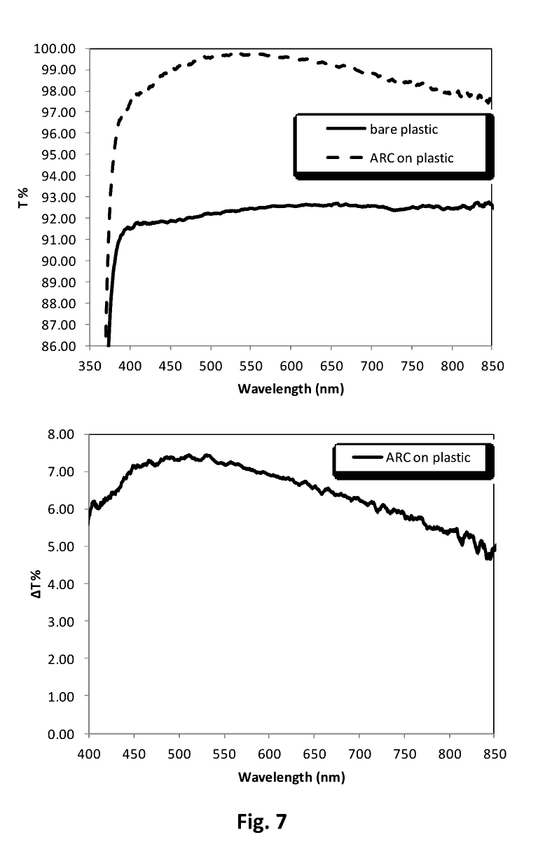

FIG. 7 shows the effect of the inventive energy transmission enhancement coating on both sides of an acrylic (PMMA) substrate. The comparison between the coated transmission spectra of a PMMA substrate with the innovative coating (dashed curve) to the same substrate uncoated (solid curve) is shown in the upper graph. The lower graph of FIG. 7 shows that the inventive coating resulted in an average increase of transmittance of 6.75% across the visible spectrum from 400 to 750 nm

Abrasion resistance of the low-temperature curable energy transmission enhancement coating is demonstrated in FIG. 8. The abrasion scrub test experiments were carried out with 2000 strokes of a brush meeting ASTM D2486 standards with 500 g of force over the coating. FIG. 8 shows the transmission spectrum of a single layer of the inventive AR coating over the wavelength range between 400-900 nm, before and after the abrasion test, where the solid red curve represents the spectrum of a virgin single-pass coating before the abrasion resistance test, and the broken curve was measured after the abrasion test.

FIG. 9 compares the change in transmittance over the indicated spectrum for the coating before and after the abrasion test. The data show only a 0.3% average decrease in the transmission of light after completion of the abrasion resistance test, indicating that over 90% of the virgin film was retained after the test, therefore demonstrating that the single-layer film has a high degree of scratch resistance. The lower solid curve represents the transmission spectrum of the bare glass substrate, showing that the AR coating provides for an average of a 3.5% increase in light transmission through the substrate, almost 100% suppression of reflection by the novel AR coating.

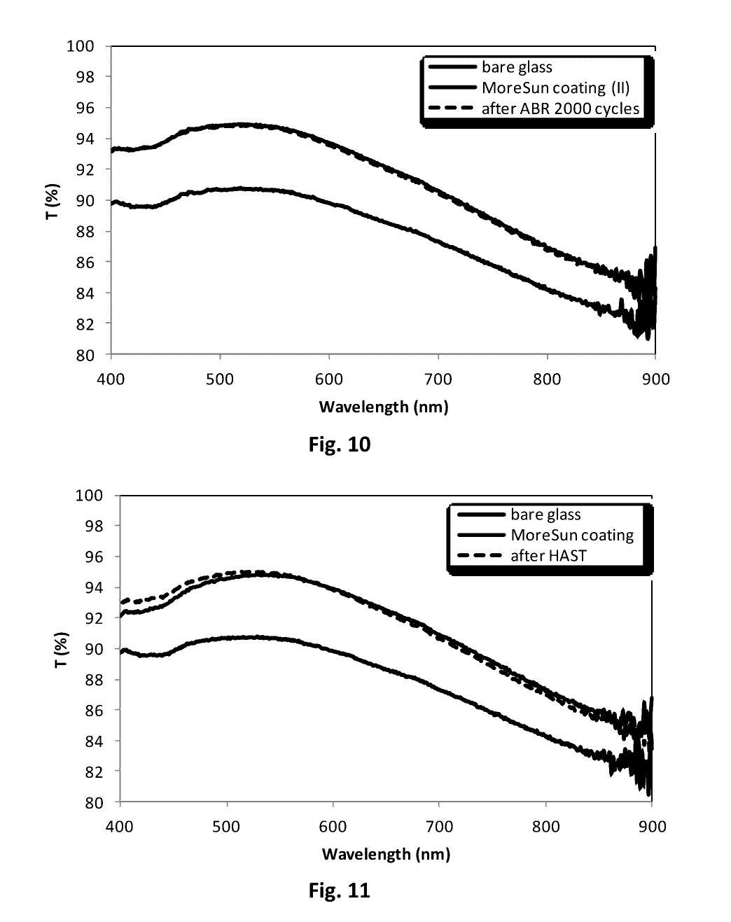

FIG. 10 shows results from the same abrasion scrub test applied to a double-pass energy transmission enhancement coating. Again, the solid red curve shows the transmission spectrum of the virgin double-layer coating, and the broken curve is the resulting transmission spectrum after the abrasion test. The data here show that the change in the optical characteristics is only about 0.09%, indicating over 97% of the coating was retained. The results here demonstrate that the double-layer coating exhibits a greater degree if robustness than the single-layer.

The moisture degradation performance of the inventive films is measured and shown in FIG. 11. The data in this figure are taken from subjecting the inventive AR coatings to conditions dictated by the industry-standard Highly Accelerated Stress Test (HAST). In this test, the coatings were subjected to high temperature of 140 C, 85% humidity at approximately 30 psi (2 atmospheres) of pressure. Under these conditions, the HAST test simulates humidity degradation over a 20 year period. The solid red curve of FIG. 11 is the optical transmission spectrum of the coating on a glass substrate before the test. The blue curve is the transmission spectrum of the coating after the test, whereas the lower solid curve is the transmission spectrum of the bare glass substrate. The results here show that the before and after change of transmission characteristics of the coating is about 0.06%, which indicates that over 98% of the coating was retained after the HAST process.

While the forgoing embodiments disclosed above describe the innovation in its various manifestations, the foregoing embodiments are to be understood by persons skilled in the art as exemplary in nature, and are in no way intended to be construed as the only embodiments possible for the innovation. Those skilled in the art will also understand that other embodiments and examples of deployment of the inventive AR coatings are conceivable and possible without departing from the scope and spirit of the innovation.

1. A single layer energy transmission enhancement coating, comprising a composition of 60-100% silicate, 0-20% siloxane, and 0-20% solid silica nanoparticles having a size range of 5-200 nm, and exhibiting an abrasion test result of over 65% when said coating is subject to an abrasion test consisting of 2000 strokes with a 1 cm×1 cm felt pad with 500 g of force over the coating and having a HAST result of over 95%.

2. A multiple layer energy transmission enhancement coating, comprising a composition of 60-100% silicate, 0-20% siloxane, and 0-20% hollow silica nanoparticles of a size range of 5-200 nm, and exhibiting an abrasion test result of over 85% when said coating is subject to an abrasion test consisting of 2000 strokes with a 1 cm×1 cm felt pad with 500 g of force over the coating and having a HAST result of over 95%.

3. A single layer energy transmission enhancement coating produced by the process comprising the steps of:
i) providing a substrate in an ambient;
ii) providing a coating apparatus having a coating distribution means adapted to distribute a liquid energy transmission enhancement coating solution on a surface of the substrate;
iii) engaging the coating apparatus with the substrate wherein the coating distribution means of the coating apparatus is in functional proximity of the substrate;
iv) depositing the liquid energy transmission enhancement coating solution from the distribution means of the coating apparatus onto the substrate surface wherein the distribution means is adapted to the cover at least a portion of the substrate surface; and
v) curing the deposited coating solution in the ambient at ambient temperatures less than or equal to 60° C. for a time period less than 24 hours, wherein the resulting cured single-layer has a composition of 60-100% silicate, 0-20% siloxane, and 0-20% solid silica nanoparticles having a size range of ( ) and exhibiting an abrasion test result of over 65% when said coating is subject to an abrasion test consisting of 200 strokes with a 1 cm×1 cm felt pad with 400 g of force over the coating and having a HAST result of over 95%.

4. The method of claim 3, wherein the substrate is a photovoltaic panel.

5. The method of claim 4, where the substrate is a photovoltaic panel array.

6. The method of claim 3, wherein the substrate is a solar thermal panel.

7. The method of claim 3, wherein the substrate is a glass window pane.

8. The method of claim 3, wherein the ambient is out of doors.

9. The method of claim 3, wherein the ambient is indoors.

10. A method for depositing an energy transmission enhancement coating on a substrate, comprising:
i) providing a substrate in an ambient;
ii) providing a coating apparatus having a coating distribution means adapted to distribute a liquid energy transmission enhancement coating solution on a surface of the substrate;
iii) engaging the coating apparatus with the substrate wherein the coating distribution means of the coating apparatus is in functional proximity of the substrate; and
iv) depositing the liquid energy transmission enhancement coating solution from the distribution means of the coating apparatus onto the substrate surface wherein the distribution means is adapted to the cover at least a portion of the substrate surface.

11. The method of claim 10, further comprising the step of curing the deposited coating solution in the ambient at ambient temperatures less than or equal to 50° C. for a time period less than 24 hours.

12. The method of claim 10, wherein the substrate is a photovoltaic panel.

13. The method of claim 12, where the substrate is a photovoltaic panel array.

14. The method of claim 10, wherein the substrate is a solar thermal panel.

15. The method of claim 10, wherein the substrate is a glass window pane.

16. The method of claim 10, wherein the ambient is out of doors.

17. The method of claim 10, wherein the ambient is indoors.

18. The method of claim 10, wherein the step of curing the deposited coating solution comprises sun curing of the deposited film.

19. The method of claim 10, wherein the step of curing the deposited coating solution comprises curing the deposited film in a dark environment.

20. A method for depositing a uniform fluid film with a thickness of less than 20 microns on a substrate located outdoors, comprising:
i) providing a substrate in an outdoor environment;
ii) providing a coating apparatus having a coating distribution means adapted to distribute a liquid energy transmission enhancement coating solution on a surface of the substrate; and
iii) depositing the liquid energy transmission enhancement coating solution from the distribution means of the coating apparatus onto the substrate surface wherein the distribution means is adapted to the cover at least a portion of the substrate surface.

21. The method of claim 20, further comprising the step of curing the deposited coating solution in the outdoor temperatures at ambient temperatures less than or equal to 50° C. for a time period less than 24 hours to yield a performance enhancement coating.

22. The method of claim 21, wherein the step of curing the deposited coating solution in the outdoor environment comprises sun-curing the deposited coating solution.

23. The method of claim 21, wherein the performance enhancement coating is an energy transmission enhancement coating.

24. The method of claim 22, where the performance enhancement coating is substantially transparent.

25. The method of claim 22, where the performance enhancement coating is abrasion resistant according to ASTM D 2486.

26. The method of claim 22, where the performance enhancement coating is humidity resistant according to JESD22-A102B.

27. The method of claim 20, wherein the substrate is a glass window pane.

28. The method of claim 20, wherein the ambient is a solar panel.
